(19) United States
(12) Patent Application Publication
(10) Pub. No.: US 2026/0072819 A1
(43) Pub. Date: Mar. 12, 2026

(54) MEMORY DEVICE

(71) Applicant: Samsung Electronics Co., Ltd., Suwon-si (KR)

(72) Inventor: Hongjin KIM, Suwon-si (KR)

(73) Assignee: Samsung Electronics Co., Ltd., Suwon-si (KR)

(21) Appl. No.: 19/098,342

(22) Filed: Apr. 2, 2025

(30) Foreign Application Priority Data
Sep. 11, 2024 (KR) 10-2024-0123985

(51) Int. Cl. G06F 12/02

(52) U.S. Cl. CPC G06F 12/0223

(57) ABSTRACT

A memory device includes a first non-volatile memory, a second non-volatile memory, a first memory controller including a first interface, and the first memory controller configured to control an operation of the first non-volatile memory, and a second memory controller including a second interface, and the second memory controller configured to control an operation of the second non-volatile memory. The first memory controller and the second memory controller are connected by at least one signal line, the first memory controller and the second memory controller are configured to exchange timing information of a plurality of signals transmitted through first to fourth lanes through the signal line, and the first memory controller and the second memory controller are configured to correct a timing of the each of the plurality of signals transmitted through the first to fourth lanes, based on the timing information.

### CROSS-REFERENCE TO RELATED APPLICATION(S)

This application claims benefit of priority to Korean Patent Application No. 10-2024-0123985 filed on Sep. 11, 2024 in the Korean Intellectual Property Office, the disclosure of which is incorporated herein by reference in its entirety.

### BACKGROUND

Example embodiments of the inventive concepts relate to a memory device.

Memory devices may be divided into volatile memory devices that lose data stored when power is cut off, and non-volatile memory devices that do not lose stored data. Volatile memory devices may have faster read/write speeds, but stored content thereof may disappear when supply of external power is cut off. On the other hand, non-volatile memory devices may have slower read/write speeds, as compared to volatile memory devices, but may retain contents thereof even when supply of external power is cut off. In particular, a non-volatile memory such as a flash memory may be widely used as a storage device in various fields due to advantages thereof such as high capacity, low noise, and/or low power. Recently, research is in progress focusing on memory devices having wider bandwidth by using universal flash storage (UFS) standard memory devices to increase data processing volume and data processing speeds.

### SUMMARY

Some example embodiments the inventive concepts are to provide a memory device including two memory controllers connected by at least one signal line, transmitting signals through four lanes, exchanging timing information through the at least one signal line, and correcting timing of signals transmitted through the four lanes.

According to some example embodiments of the inventive concepts a memory device includes a first non-volatile memory, a second non-volatile memory, a first memory controller including a first interface, and the first memory controller configured to control an operation of the first non-volatile memory, and a second memory controller including a second interface, and the second memory controller configured to control an operation of the second non-volatile memory. The first interface includes a first lane configured to transmit a first differential input signal pair to the first memory controller, and a second lane configured to transmit a second differential output signal pair from the first memory controller, the second interface includes a third lane configured to transmit a third differential input signal pair to the second memory controller receives, and a fourth lane configured to transmit a fourth differential output signal pair from second memory controller, and the first memory controller and the second memory controller are connected by at least one signal line, the first memory controller and the second memory controller are configured to exchange timing information of a plurality of signals transmitted through the first to fourth lanes through the signal line, and the first memory controller and the second memory controller are configured to correct a timing of the each of the plurality of signals transmitted through the first to fourth lanes, based on the timing information.

According to some example embodiments of the inventive concepts a memory device includes a first non-volatile memory, a second non-volatile memory, a first memory controller configured to control an operation of the first non-volatile memory, and a second memory controller configured to control an operation of the second non-volatile memory. The first memory controller and the second memory controller are connected by at least one signal line, and the at least one of the first memory controller or the second memory controller is configured to limit performance of the at least one of the first memory controller or the second memory controller based on a temperature of at least one of the first memory controller or the second memory controller exceeding a reference temperature, and the at least one of the first memory controller or the second memory controller is configured to limit performance of other memory controller through the at least one signal line.

According to some example embodiments of the inventive concepts a memory device includes a first non-volatile memory, a second non-volatile memory, a first memory controller configured to control an operation of the first non-volatile memory, and a second memory controller configured to control an operation of the second non-volatile memory. The first memory controller and the second memory controller are connected by at least one signal line, the second memory controller is configured to request a corrected timing information of a signal transmitted to and received from the first memory controller, and the first memory controller is configured to provide the corrected timing information to the second memory controller through the at least one signal line.

### BRIEF DESCRIPTION OF DRAWINGS

The above and other aspects, features, and advantages of some example embodiments of the inventive concepts will be more clearly understood from the following detailed description, taken in conjunction with the accompanying drawings, in which:

FIG. 1 is a block diagram simply illustrating a system including a memory device according to some example embodiments.

FIGS. 2 and 3 are block diagrams simply illustrating a memory device according to some example embodiments.

FIG. 4 is a flow chart simply illustrating an operation of a memory device according to some example embodiments.

FIGS. 5 and 6 are views simply illustrating an operation of a memory device according to some example embodiments.

FIG. 7 is a flow chart simply illustrating an operation of a memory device according to some example embodiments.

FIG. 8 is a view simply illustrating an operation of a memory device according to some example embodiments.

FIG. 9 is a flow chart simply illustrating an operation of a memory device according to some example embodiments.

FIG. 10 is a view simply illustrating an operation of a memory device according to some example embodiments.

FIG. 11 is a flow chart simply illustrating an operation of a memory device according to some example embodiments.

FIGS. 12 and 13 are views simply illustrating an operation of a memory device according to some example embodiments.

### DETAILED DESCRIPTION

Hereinafter, some example embodiments will be described with reference to the attached drawings as follows.

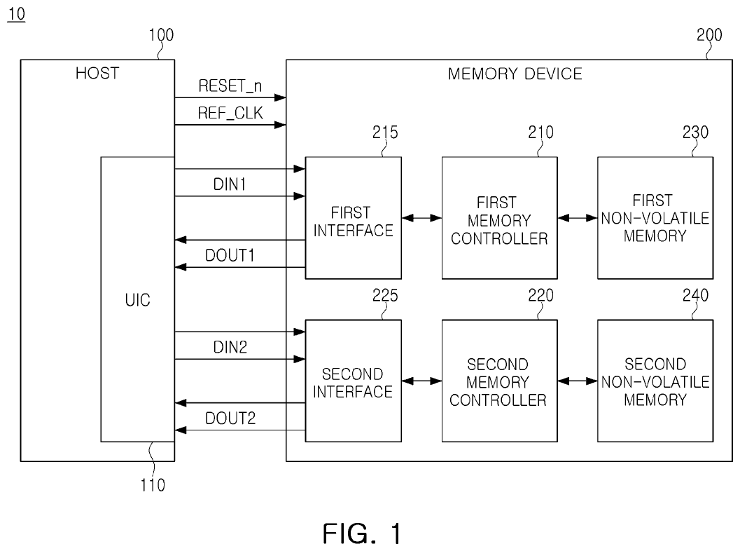

FIG. 1 is a block diagram simply illustrating a system including a memory device according to some example embodiments.

A system 10 according to some example embodiments may be a system that follows a universal flash storage (UFS) standard announced by a joint electron device engineering council (JEDEC), and may include a host 100 and a memory device 200.

The system 10 may be a mobile system such as a mobile phone, a smartphone, a tablet personal computer, a wearable device, a healthcare device, or an internet-of-things (IOT) device. The system 10 illustrated in FIG. 1 is not necessarily limited to the mobile system, and may be a personal computer, a laptop computer, a server, a media player, an automotive device such as a navigation system, or the like.

The host 100 may control an overall operation of the system 10, specifically, an operation of other components forming the system 10. In some example embodiments, the host 100 may be implemented as a portion of an application processor. The host 100 may include a host controller, an application, a UFS driver, a host memory, a UFS interconnect (UIC) layer 110, and the like. However, example embodiments are not limited thereto.

The memory device 200 may function as a non-volatile storage device storing data regardless of whether power is supplied, and may have a relatively large amount of storage capacity. The memory device 200 may include an interface (215 and 225), a memory controller (210 and 220), a non-volatile memory (230 and 240), and the like. An input signal and an output signal may be transmitted and received through the UIC layer 110 of the host 100 and the interface (215 and 225) of the memory device 200. Referring to FIG. 1, the memory controller (210 and 220) and the interface (215 and 225) may be illustrated separately, but example embodiments are not limited thereto, and the memory controller (210 and 220) may include the interface (215 and 225).

The memory device 200 may include the memory controller (210 and 220) and the non-volatile memory (230 and 240) storing data under control of the memory controller (210 and 220). The non-volatile memory (230 and 240) may be composed of a plurality of memory units, and such memory units may include a vertical NAND (V-NAND) flash memory of a 2D structure or a 3D structure, but may also include other types of non-volatile memory such as a PRAM and/or an RRAM, or the like. However, example embodiments are not limited thereto.

The memory device 200 may be included in the system 10 in a state being physically separated from the host 100, or may be implemented in the same package as the host 100. In addition, the memory device 200 may have a form such as a solid state device (SSD) or a memory card. Such a memory device 200 may be a device to which a standard specification such as an UFS, an embedded multi-media card (eMMC), or a non-volatile memory express (NVMe) may be applied, but example embodiments are not limited thereto.

A first interface 215 and a second interface 225 may provide a connection through which the host 100 and the memory device 200 may exchange data. The first interface 215 and the second interface 225 may include MIPI M-PHY, MIPI UniPro, or the like, respectively. However, example embodiments are not limited thereto. The UIC layer 110 of the host 100 may also include MIPI M-PHY and MIPI UniPro.

The first interface 215 and the second interface 225 may support a plurality of lanes, and each of the lanes may be implemented as a differential line pair. For example, the first interface 215 may include at least one receive lane and at least one transmit lane. Referring to FIG. 1, a pair of lines transmitting a differential input signal pair may constitute a receive lane DIN1, and a pair of lines transmitting a differential output signal pair may constitute a transmit lane DOUT1.

A receive lane (DIN1 AND DIN2) and a transmit lane (DOUT1 AND DOUT2) may transmit data in a serial communication manner, and may communicate in a full-duplex communication manner between the host 100 and the memory device 200 due to a structure in which the receive lane (DIN1 and DIN2) and the transmit lane (DOUT1 and DOUT2) are separated. For example, the memory device 200 may transmit data to the host 100 through the transmit lane (DOUT1 and DOUT2), even when receiving data from the host 100 through the receive lane (DIN1 and DIN2). In addition, control data such as commands from the host 100 to the memory device 200, and user data that the host 100 wants to store in the non-volatile memory (230 and 240) of the memory device 200 or read from the non-volatile memory (230 and 240) may be transmitted through the same lane.

The host 100 may transmit a reference clock REF_CLK and a hardware reset signal RESET_n for the memory device 200 to the memory device 200. A frequency value of the reference clock REF_CLK provided from the host 100 to the memory device 200 may be one of four values of 19.2 MHz, 26 MHz, 38.4 MHz, and 52 MHz, but is not necessarily limited thereto. Even when transmission and reception of data are performed between the host 100 and the memory device 200, the frequency value of the reference clock REF_CLK may be changed. The memory device 200 may generate clocks of various frequencies from the reference clock REF_CLK provided from the host 100 by using a phase-locked loop (PLL) or the like. In addition, the host 100 may also set a value of a data rate between the host 100 and the memory device 200 through the frequency value of the reference clock REF_CLK. For example, the value of the data rate may be determined depending on the frequency value of the reference clock REF_CLK.

A system 10 according to some example embodiments may include two lanes DIN1 and DIN2 for transmitting a differential input signal pair, and two lanes DOUT1 and DOUT2 for transmitting a differential output signal pair.

The first interface 215 may receive a first differential input signal pair through a first lane DIN1, and may transmit a second differential output signal pair through a second lane DOUT1. The second interface 225 may receive a third differential input signal pair through a third lane DIN2, and may transmit a fourth differential output signal pair through a fourth lane DOUT2. The system 10 may transmit a signal between the host 100 and the memory device 200 through a total of four lanes DIN1, DOUT1, DIN2, and DOUT2, and may improve a bandwidth of the system 10. In some example embodiments, the first differential input signal pair and the third differential input signal pair may be signal pairs, independent of each other, and the second differential output signal pair and the fourth differential output signal pair may be signal pairs, independent of each other.

In some example embodiments, the system 10 may be a system providing UFS4.0, and a signal transmitted through each of the lanes DIN1, DOUT1, DIN2, and DOUT2 may be transmitted at a high speed of about 24 Gbps. When timing skew occurs in the signal transmitted through each of the lanes DIN1, DOUT1, DIN2, and DOUT2, performance of the system 10 may be degraded.

In some example embodiments, a first memory controller 210 and a second memory controller 220, included in the memory device 200, may be connected by at least one signal line. The first memory controller 210 and the second memory controller 220 may exchange timing information of the signal transmitted through each of the lanes DIN1, DOUT1, DIN2, and DOUT2 through the at least one signal line, and the first memory controller 210 and the second memory controller 220 may correct timing of the signal transmitted through each of the lanes DIN1, DOUT1, DIN2, and DOUT2, based on the timing information.

For example, the first memory controller 210 may internally correct the timing of the signals transmitted through the first lane DIN1 and the second lane DOUT1, and the second memory controller 220 may also internally correct the timing of the signals transmitted through the third lane DIN2 and the fourth lane DOUT2. The second memory controller 220 may correct the timing of the signals transmitted through the third lane DIN2 and the fourth lane DOUT2 by referring to the timing information provided from the first memory controller 210 through the at least one signal line. Therefore, timing skew of the signals transmitted through the first to fourth lanes DIN1, DOUT1, DIN2, and DOUT2 may be minimized. A specific operation for correcting the timing will be described later with reference to each drawing.

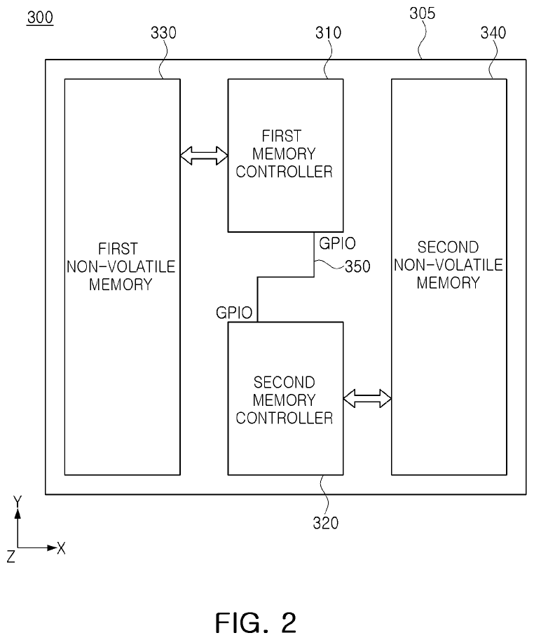

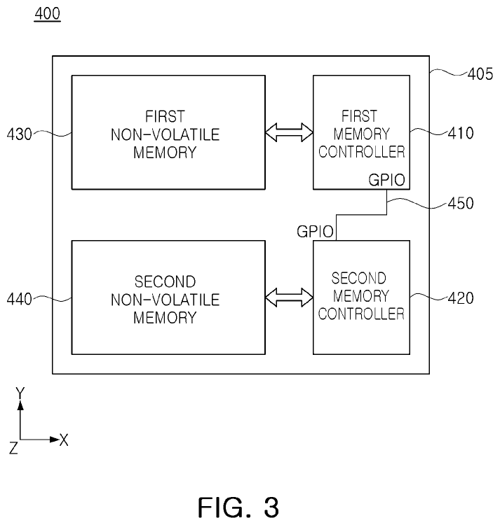

FIGS. 2 and 3 are block diagrams simply illustrating a memory device according to some example embodiments.

A memory device 300 according to some example embodiments may include a first memory controller 310, a second memory controller 320, a first non-volatile memory 330, and a second non-volatile memory 340. The first memory controller 310 may control an operation of the first non-volatile memory 330, and the second memory controller 320 may control an operation of the second non-volatile memory 340.

The first memory controller 310 may include a first interface, and the second memory controller 320 may include a second interface. The first interface may receive a first differential input signal pair through a first lane, and may transmit a second differential output signal pair through a second lane. The second interface may receive a third differential input signal pair through a third lane, and may transmit a fourth differential output signal pair through a fourth lane.

The memory device 300 may include the first memory controller 310 and the second memory controller 320, to transmit a signal through a total of four lanes, and may improve a bandwidth of the memory device 300. Since each signal transmitted through the first to fourth lanes may be transmitted at a high speed, when timing skew occurs in the signal transmitted through the first to fourth lanes, performance of the memory device may be degraded.

In some example embodiments, the first memory controller 310 and the second memory controller 320 may be connected through at least one signal line 350. For example, a general purpose input output (GPIO) pin of the first memory controller 310 and a GPIO pin of the second memory controller 320 may be connected through the at least one signal line 350.

The first memory controller 310 and the second memory controller 320 may exchange timing information of a signal transmitted through each of the lanes through the at least one signal line, and the first memory controller 310 and the second memory controller 320 may correct timing of the signal transmitted through each of the lanes, based on the timing information.

The first memory controller 310 may internally correct the timing of the signals transmitted through the first lane and the second lane, and the second memory controller 320 may also internally correct the timing of the signals transmitted through the third lane and the fourth lane.

The second memory controller 320 may request the first memory controller 310 for corrected timing information of the first lane and the second lane, and the first memory controller 310 may provide the corrected timing information to the second memory controller 320 through the at least one signal line. The second memory controller 320 may correct timing of the signals transmitted through the third lane and the fourth lane, based on timing provided from the first memory controller 310.

Referring to FIG. 2, the memory device 300 may further include a package substrate 305. The first memory controller 310, the second memory controller 320, the first non-volatile memory 330, and the second non-volatile memory 340 may be mounted on the package substrate 305.

In some example embodiments, the first memory controller 310 and the second memory controller 320 may be connected to the package substrate 305 through a plurality of pads. The first non-volatile memory 330 and the second non-volatile memory 340 may be connected to the package substrate 305 through a plurality of wires.

A first signal line connecting the first memory controller 310 and the first non-volatile memory 330, and a second signal line connecting the second memory controller 320 and the second non-volatile memory 340 may be disposed in one layer on the package substrate 305. In some example embodiments, the first signal line, the second signal line, and the at least one signal line connecting the first memory controller 310 and the second memory controller 320 may not overlap in one layer on the package substrate.

In some example embodiments, the first non-volatile memory 330 and the second non-volatile memory 340 may be disposed on the package substrate 305 in a first direction (X-axis direction), parallel to an upper surface of the package substrate 305. The first memory controller 310 and the second memory controller 320 may be disposed between the first non-volatile memory 330 and the second non-volatile memory 340 in the first direction (X-axis direction). In some example embodiments, the first memory controller 310 may be disposed on the package substrate 305, and the second memory controller 320 may be disposed below the first memory controller 310 in a second direction (Y-axis direction), perpendicular to the first direction (X-axis direction) and parallel to the upper surface of the package substrate 305.

Referring to FIG. 3, a memory device 400 may further include a package substrate 405. A first memory controller 410, a second memory controller 420, a first non-volatile memory 430, and a second non-volatile memory 440 may be mounted on a package substrate 405.

In some example embodiments, the first memory controller 410 and the first non-volatile memory 430 may be disposed in a first direction (X-axis direction), parallel to an upper surface of the package substrate 405. In a second direction (Y-axis direction) perpendicular to the first direction (X-axis direction) and parallel to the upper surface of the package substrate 405, the second memory controller 420 may be disposed below the first memory controller 410, and the second non-volatile memory 440 may be disposed below the first non-volatile memory 430. The first memory controller 410 and the second memory controller 420 may be connected by at least one signal line 450. Arrangement of the first non-volatile memory, the second non-volatile memory, the first memory controller, and the second memory controller, as illustrated in FIGS. 2 and 3, is not limited, and may be different from those illustrated in FIGS. 2 and 3 on the package substrate.

In some example embodiments, the first memory controller 410 and the second memory controller 420 may be the same memory controllers. The second memory controller 420 may be disposed on the package substrate 405 to rotate the first memory controller 410 180 degrees. Since the first memory controller 410 and the second memory controller 420, included in the memory device 400, are the same memory controllers, a period in time for separately designing or manufacturing another memory controller or another memory device may be saved.

To increase an amount of data processed by the memory device 400, a size of the memory controller may increase, but it may take a long time to manufacture the memory controller. Without increasing the size of the memory controller, the amount of data processed by the memory device 400 may increase, even when two identical memory controllers are used. In addition, since one memory controller may rotate 180 degrees while using an existing memory controller, a period in time required to manufacture a new memory controller, such as a memory controller with the left and right sides reversed for connecting two memory controllers, may be saved.

In some example embodiments, the first memory controller 410 and the second memory controller 420 may be connected by the at least one signal line 450, to adjust performance of the first memory controller 410 and the second memory controller 420 to the same extent. When the memory device operates, heat may be generated in the memory controller (410 and 420). When excessive heat is generated in the memory controller (410 and 420), performance of the memory controller (410 and 420) may be intentionally limited.

For example, when a temperature of the memory controller (410 and 420) exceeds a reference temperature, the memory controller (410 and 420) may limit performance thereof. A transmission speed of a signal transmitted to the memory controller (410 and 420), an amount of data processed, or the like may be reduced, to lower the temperature of the memory controller (410 and 420) and reduce and/or prevent break down of the memory controller (410 and 420).

The temperature of the first memory controller 410 may exceed the reference temperature, and the temperature of the second memory controller 420 may not exceed the reference temperature. When only performance of the first memory controller 410 is degraded, timing of signals transmitted through the first lane and the second lane may be different from timing of signals transmitted through the third lane and the fourth lane. When the timing of the signals transmitted through the first to fourth lanes are different, an error due to timing skew may occur.

In some example embodiments, when the temperature of at least one of the first memory controller 410 or the second memory controller 420 exceeds the reference temperature, performance of the first memory controller 410 and performance of the second memory controller 420 may be limited. Since the first memory controller 410 and the second memory controller 420 are connected by the at least one signal line 450, when performance may be limited to lower the temperature of at least one of the first memory controller 410 or the second memory controller 420, performance of the other one may also be limited. Since performance of both the first memory controller 410 and the second memory controller 420 may be lowered through at least one signal line, an error due to timing skew may be minimized.

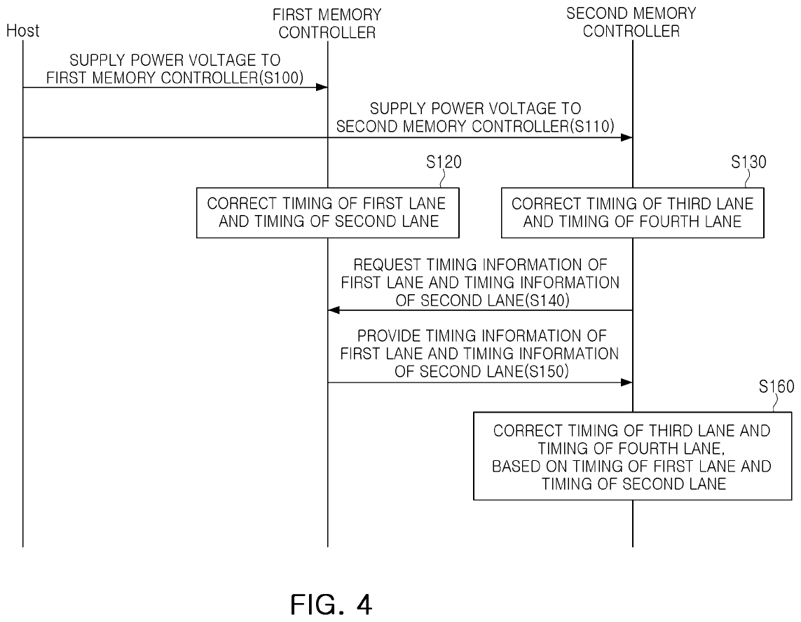

FIG. 4 is a flow chart simply illustrating an operation of a memory device according to some example embodiments.

In some example embodiments, a host may supply a power voltage to a first memory controller (S100). The host may also supply a power voltage to a second memory controller (S110). When a system is initially operated, the host may supply power to the first memory controller and the second memory controller. The host may supply power to the first memory controller and the second memory controller simultaneously, or a desired (and/or alternatively predetermined) time difference may occur.

In some example embodiments, the first memory controller may correct timing of a first lane and timing of a second lane (S120). The first memory controller may include a first interface, and the first interface may support the first lane and the second lane, which provide a path for transmitting a signal. A first differential input signal pair may be transmitted through the first lane, and a second differential output signal pair may be transmitted through the second lane. In some example embodiments, timing of a signal transmitted through the first lane may be different from timing of a signal transmitted through the second lane. The first memory controller may correct the timing of the signal transmitted through the first lane and the timing of the signal transmitted through the second lane, to match them.

In some example embodiments, the second memory controller may correct timing of a third lane and timing of a fourth lane (S130). The second memory controller may include a second interface, and the second interface may support the third lane and the fourth lane, which provide a path for transmitting a signal. A third differential input signal pair may be transmitted through the third lane, and a fourth differential output signal pair may be transmitted through the fourth lane. In some example embodiments, timing of a signal transmitted through the third lane may be different from timing of a signal transmitted through the fourth lane. The second memory controller may correct the timing of the signal transmitted through the third lane and the timing of the signal transmitted through the fourth lane, to match.

In some example embodiments, the second memory controller may request timing information of the first lane and timing information of the second lane to the first memory controller (S140). The first memory controller and the second memory controller may be connected by at least one signal line. The second memory controller may request timing information of the signal transmitted through the first lane and timing information of the signal transmitted through the second lane to the first memory controller through the at least one signal line.

In some example embodiments, the first memory controller may provide the timing information of the first lane and the timing information of the second lane to the second memory controller (S150). The first memory controller may provide the timing information of the signal transmitted through the first lane and the timing information of the signal transmitted through the second lane to the second memory controller through the at least one signal line. Since the first memory controller compensates for the timing of the signal transmitted through the first lane and the timing of the signal transmitted through the second lane, to match, the timing of the signal transmitted through the first lane and the timing of the signal transmitted through the second lane may be the same value.

In some example embodiments, the second memory controller may correct the timing of the third lane and the timing of the fourth lane, based on the timing of the first lane and the timing of the second lane, provided from the first memory controller (S160). The timing of the signal transmitted through the first lane and the timing of the signal transmitted through the second lane, provided from the first memory controller, may be one value. The second memory controller may correct the timing of the signal transmitted through the third lane and the timing of the signal transmitted through the fourth lane, to match the timing provided from the first memory controller.

A memory device according to some example embodiments may include the first memory controller and the second memory controller to transmit the signals through the four lanes, thereby improving a bandwidth of the memory device. In addition, the first memory controller and the second memory controller, included in the memory device, may exchange the timing information of the signals transmitted through the first to fourth lanes through the at least one signal line, and may correct the timing of the signals transmitted through the first to fourth lanes, based on the exchanged timing information, to reduce (and/or minimize) an error due to timing skew.

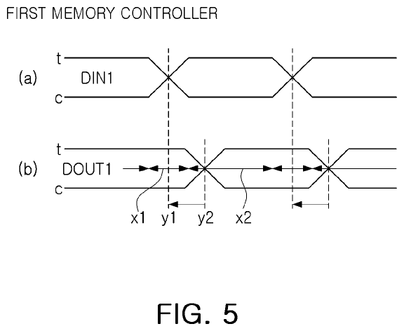

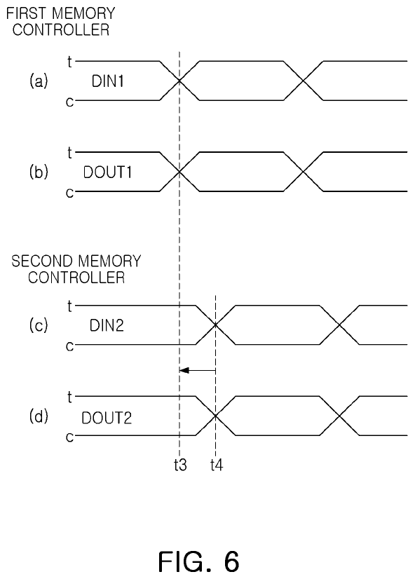

FIGS. 5 and 6 are views simply illustrating an operation of a memory device according to some example embodiments.

A memory device may include a non-volatile memory and a memory controller controlling an operation of the non-volatile memory. The memory controller may include an interface supporting a plurality of lanes. Each of the lanes constituting the plurality of lanes may be implemented as a differential line pair. For example, the interface may support at least one receive lane and at least one transmit lane.

A first interface included in a first memory controller may support the plurality of lanes. The plurality of lanes may include a first lane transmitting a differential input signal pair, and a second lane transmitting a differential output signal pair. Referring to FIG. 5, a pair of lines transmitting a differential input signal pair (DIN1_t and DIN1_c) may constitute a receive lane DIN1, and a pair of lines transmitting a differential output signal pair (DOUT1_t and DOUT1_c) may constitute a transmit lane DOUT1. In FIG. 5, one transmit lane and one receive lane are illustrated, but the number of transmit lanes and the number of receive lanes may be changed.

The first memory controller may transmit and receive signals through a first lane DIN1 and a second lane DOUT1. Timing y1 of a signal transmitted through the first lane DIN1 may be different from timing y2 of a signal transmitted through the second lane DOUT1. When timing of the first lane DIN1 is different from timing of the second lane DOUT1, since an error due to timing skew may occur, the first memory controller may correct the timing of the signal transmitted through the first lane DIN1 and the timing of the signal transmitted through the second lane DOUT1, to match.

In some example embodiments, the first memory controller may correct the timing y2 of the signal transmitted through the second lane DOUT1, based on the timing y1 of the signal transmitted through the first lane DIN1. The first memory controller may determine whether the timing y2 of the signal transmitted through the second lane DOUT1 matches the timing y1 of the signal transmitted through the first lane DIN1 while moving the timing y2. When the timing y2 of the second lane DOUT1 falls within an x2 section, the first memory controller may determine that the timing of the first lane DIN1 and the timing of the second lane DOUT1 do not match.

When the timing y2 of the second lane DOUT1 falls within an x1 section, the first memory controller may determine that the timing y2 of the second lane DOUT1 falls within a section in which the timing y2 of the second lane DOUT1 matches the timing y1 of the first lane DIN1. The first memory controller may continuously move the timing y2 of the second lane DOUT1 to find a median value of the x1 section. The first memory controller may move the median value of the x1 section and the timing y2 of the second lane DOUT1 to match, and may determine that the timing y1 of the first lane DIN1 and the timing y2 of the second lane DOUT1 match. The second memory controller according to some example embodiments may also internally correct the timing of the signal transmitted through the third lane and the timing of the signal transmitted through the fourth lane in the same manner as described above.

Referring to FIG. 6, a memory device according to some example embodiments may include a first memory controller including a first interface and a second memory controller including a second interface. The first interface may receive a first differential input signal pair (DIN1_t and DIN1_c) through a first lane DIN1, and may transmit a second differential output signal pair (DOUT1_t and DOUT1_c) through a second lane DOUT1. The second interface may receive a third differential input signal pair (DIN2_t and DIN2_c) through a third lane DIN2, and may transmit a fourth differential output signal pair (DOUT2_t and DOUT2_c) through a fourth lane DOUT2.

The first memory controller may internally correct timing of a signal transmitted through the first lane DIN1 and timing of a signal transmitted through the second lane DOUT1. Corrected timing of the signal transmitted through the first lane DIN1 and corrected timing of the signal transmitted through the second lane DOUT1 in the first memory controller may be the same as t3. The second memory controller may internally correct timing of a signal transmitted through the third lane DIN2 and timing of a signal transmitted through the fourth lane DOUT2. Corrected timing of the signal transmitted through the third lane DIN2 and corrected timing of the signal transmitted through the fourth lane DOUT2 in the second memory controller may be the same as t4.

In some example embodiments, the second memory controller may request corrected timing information of the first lane DIN1 and corrected timing information of the second lane DOUT1 from the first memory controller. The first memory controller may provide the corrected timing information of the first lane DIN1 and the corrected timing information of the second lane DOUT1 to the second memory controller. The second memory controller may re-correct corrected timing t4 of the third lane DIN2 and corrected timing t4 of the fourth lane DOUT2, to match corrected timing t3 of the first lane DIN1 and corrected timing t3 of the second lane DOUT1 in the first memory controller. The second memory controller may find timing matching the corrected timing t3 of the first lane DIN1 and timing matching the corrected timing t3 of the second lane DOUT1 while moving timing t4 of the third lane DIN2 and timing t4 of the fourth lane DOUT2.

A memory device according to some example embodiments may include the first memory controller and the second memory controller, to transmit signals through the first to fourth lanes DIN1, DOUT1, DIN2, and DOUT2, and improve a bandwidth of the memory device. In addition, the first memory controller and the second memory controller may exchange timing information of a signal transmitted to each of the lanes DIN1, DOUT1, DIN2, and DOUT2 through at least one signal line, and may correct timing of each of the lanes DIN1, DOUT1, DIN2, and DOUT2, to reduce (and/or minimize) an error due to timing skew.

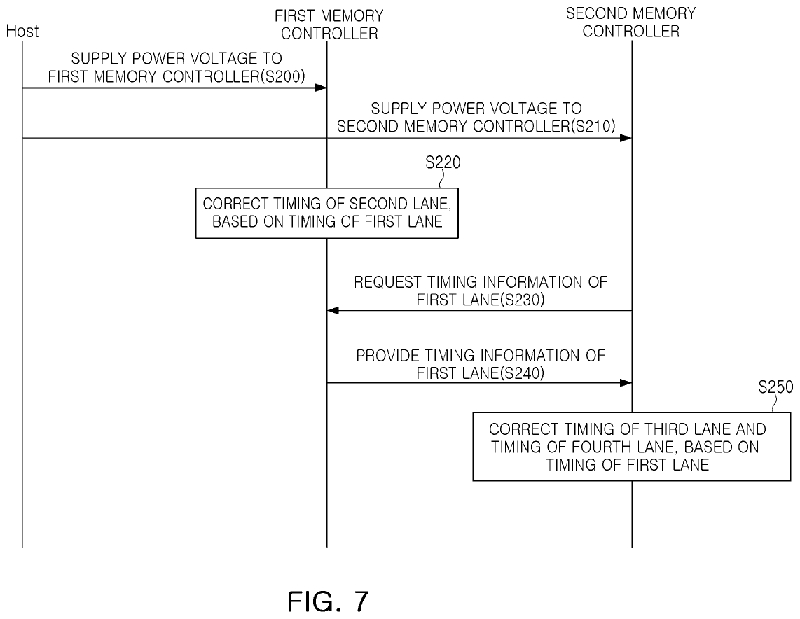

FIG. 7 is a flow chart simply illustrating an operation of a memory device according to some example embodiments.

In some example embodiments, a host may supply a power voltage to a first memory controller (S200). The host may also supply a power voltage to a second memory controller (S210). When a system is initially operated, the host may supply power to the first memory controller and the second memory controller. The host may supply power to the first memory controller and the second memory controller simultaneously, or a desired (and/or alternatively predetermined) time difference may occur.

In some example embodiments, the first memory controller may correct timing of a second lane, based on timing of a first lane (S220). In some example embodiments, timing of a signal transmitted through the first lane may be different from timing of a signal transmitted through the second lane. The first memory controller may correct to match the timing of the signal transmitted through the second lane, based on the timing of the signal transmitted through the first lane. When the first memory controller corrects the timing of the second lane, the second memory controller may not correct timing of the third lane and timing of the fourth lane.

In some example embodiments, the second memory controller may request timing information of the first lane from the first memory controller (S230). The first memory controller and the second memory controller may be connected by at least one signal line. The second memory controller may request timing information of the signal transmitted through the first lane from the first memory controller through the at least one signal line.

In some example embodiments, the first memory controller may provide the timing information of the first lane to the second memory controller (S240). The first memory controller may provide the timing information of the signal transmitted through the first lane to the second memory controller through the at least one signal line. Since the first memory controller corrects the timing of the second lane, based on the timing of the first lane, the first memory controller may provide the timing information of the first lane.

In some example embodiments, the second memory controller may correct the timing of the third lane and the timing of the fourth lane, based on the timing of the first lane (S250). The second memory controller may find a section matching the timing of the first lane while moving the timing of the third lane and the timing of the fourth lane. The first memory controller and the second memory controller may correct the timing of each of the signals transmitted through the first to fourth lanes to match.

A memory device according to some example embodiments may include the first memory controller and the second memory controller, to transmit signals through the first to fourth lanes and improve a bandwidth of the memory device. In addition, the first memory controller and the second memory controller may exchange timing information through the at least one signal line, and may correct the timing of the signals transmitted to each of the lanes, to reduce (and/or minimize) an error due to timing skew.

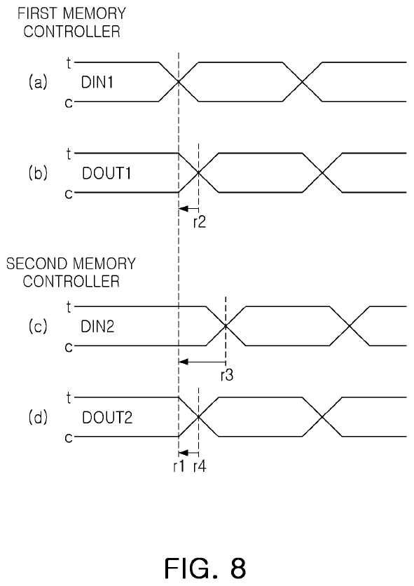

FIG. 8 is a view simply illustrating an operation of a memory device according to some example embodiments.

A memory device according to some example embodiments may include a first memory controller and a second memory controller. A first interface included in the first memory controller may support a first lane DIN1 transmitting a differential input signal pair, and a second lane DOUT1 transmitting a differential output signal pair. A second interface included in the second memory controller may support a third lane DIN2 transmitting a differential input signal pair, and a fourth lane DOUT2 transmitting a differential output signal pair.

The first memory controller may correct timing of the first lane DIN1 and timing of the second lane DOUT1. In some example embodiments, the first memory controller may correct timing r2 of a signal transmitted through the second lane DOUT1, based on timing r1 of a signal transmitted through the first lane DIN1. Corrected timing of the first lane DIN1 and corrected timing of the second lane DOUT1 may coincide with r1.

The second memory controller may request timing r1 information of the first lane DIN1 from the first memory controller. The first memory controller may provide the timing r1 information of the first lane DIN1 to the second memory controller. The second memory controller may correct timing r3 of the third lane DIN2 and timing r4 of the fourth lane DOUT2, to match timing r1 of the first lane DIN1. The second memory controller may move timing r3 of a signal transmitted through the third lane DIN2 and timing r4 of a signal transmitted through the fourth lane DOUT2 to match the timing r1 of the first lane DIN1. Therefore, the timing of each of the signals transmitted through the first to fourth lanes DIN1, DOUT1, DIN2, and DOUT2 may all be the same as r1.

A memory device according to some example embodiments may include the first memory controller and the second memory controller, to transmit a signal through the first to fourth lanes DIN1, DOUT1, DIN2, and DOUT2, and improve a bandwidth of the memory device. In addition, the first memory controller and the second memory controller may exchange timing information through at least one signal line, and may correct the timing of the signals transmitted to each of the lanes DIN1, DOUT1, DIN2, and DOUT2, to reduce (and/or minimize) an error due to timing skew.

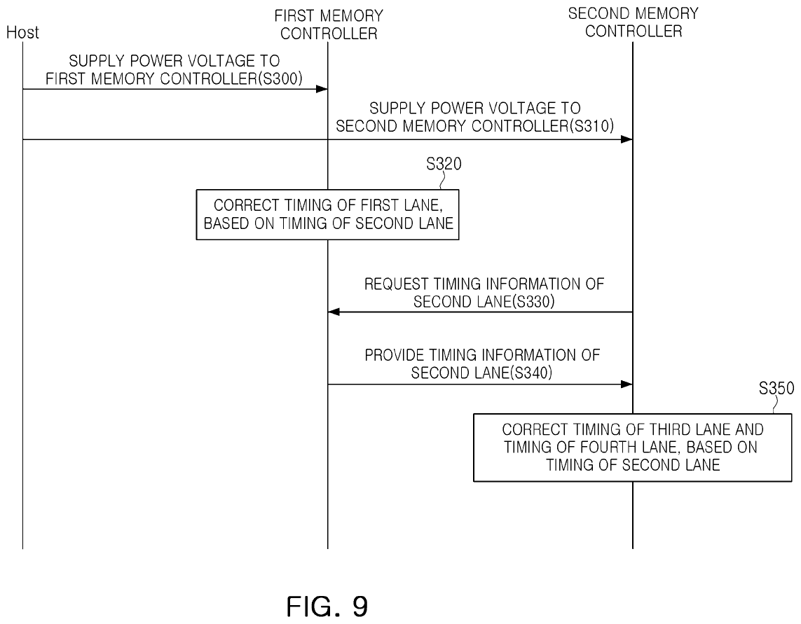

FIG. 9 is a flow chart simply illustrating an operation of a memory device according to some example embodiments.

In some example embodiments, a host may supply a power voltage to a first memory controller (S300). The host may also supply a power voltage to a second memory controller (S310). When a system is initially operated, the host may supply power to the first memory controller and the second memory controller. The host may supply power to the first memory controller and the second memory controller simultaneously, or a desired (and/or alternatively predetermined) time difference may occur.

In some example embodiments, the first memory controller may correct timing of a first lane, based on timing of a second lane (S320). In some example embodiments, timing of a signal transmitted through the first lane may be different from timing of a signal transmitted through the second lane. The first memory controller may correct the timing of the signal transmitted through the first lane, to match the timing of the signal transmitted through the second lane. When the timing of the first lane is corrected in the first memory controller, the second memory controller may not correct timing of a third lane and timing of a fourth lane.

In some example embodiments, the second memory controller may request timing information of the second lane to the first memory controller (S330). The second memory controller may request timing information of a signal transmitted in the second lane to the first memory controller through at least one signal line.

In some example embodiments, the first memory controller may provide the timing information of the second lane to the second memory controller (S340). The first memory controller may provide the timing information of the signal transmitted in the second lane to the second memory controller through the at least one signal line.

In some example embodiments, the second memory controller may correct the timing of the third lane and the timing of the fourth lane, based on the timing of the second lane (S350). The second memory controller may find a section matching the timing of the second lane while moving the timing of the third lane and the timing of the fourth lane. The second memory controller may correct timing of a signal transmitted through the third lane and timing of a signal transmitted through the fourth lane, after receiving the timing information of the second lane from the first memory controller.

A memory device according to some example embodiments may include the first memory controller and the second memory controller, to transmit a signal through the first to fourth lanes and improve a bandwidth of the memory device. In addition, the first memory controller and the second memory controller may exchange timing information through the at least one signal line, and may correct the timing of the signals transmitted to each of the lanes, to reduce (and/or minimize) an error due to timing skew.

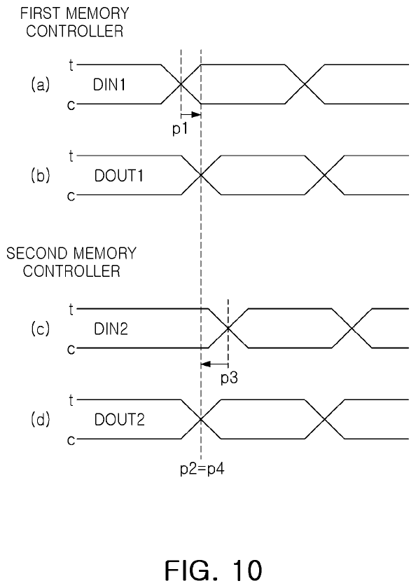

FIG. 10 is a view simply illustrating an operation of a memory device according to some example embodiments.

A memory device according to some example embodiments may include a first memory controller and a second memory controller. A first interface included in the first memory controller may support a first lane DIN1 transmitting a differential input signal pair, and a second lane DOUT1 transmitting a differential output signal pair. A second interface included in the second memory controller may support a third lane DIN2 transmitting a differential input signal pair, and a fourth lane DOUT2 transmitting a differential output signal pair.

The first memory controller may correct timing of the first lane DIN1 and timing of the second lane DOUT1. In some example embodiments, the first memory controller may correct timing p1 of a signal transmitted through the first lane DIN1, based on timing p2 of a signal transmitted through the second lane DOUT1. Corrected timing of the signal transmitted through the first lane DIN1 and the timing of the signal transmitted through the second lane DOUT1 may be the same as p2.

The second memory controller may request timing p1 information of the second lane DOUT1 from the first memory controller. The first memory controller may provide the timing p1 information of the second lane DOUT1 to the second memory controller. The second memory controller may correct timing p3 of a signal transmitted through the third lane DIN2 and timing p4 of a signal transmitted through the fourth lane DOUT2, to match the timing p2 of the signal transmitted through the second lane DOUT1.

The second memory controller may move the timing p3 of the signal transmitted through the third lane DIN2 and the timing p4 of the signal transmitted through the fourth lane DOUT2 to match the timing p2 of the signal transmitted through the second lane DOUT1. In some example embodiments, the timing p2 of the second lane DOUT1 and the timing p4 of the fourth lane DOUT2 may be the same. When correction of the timing is completed in the first memory controller and the second memory controller, the timing of each of the signals transmitted through the first to fourth lanes DIN1, DOUT1, DIN2, and DOUT2 may all be the same as p2.

A memory device according to some example embodiments may include the first memory controller and the second memory controller, to transmit a signal through the first to fourth lanes DIN1, DOUT1, DIN2, and DOUT2, and improve a bandwidth of the memory device. In addition, the first memory controller and the second memory controller may exchange timing information through at least one signal line, and may correct the timing of the signals transmitted to each of the lanes DIN1, DOUT1, DIN2, and DOUT2, to reduce (and/or minimize) an error due to timing skew.

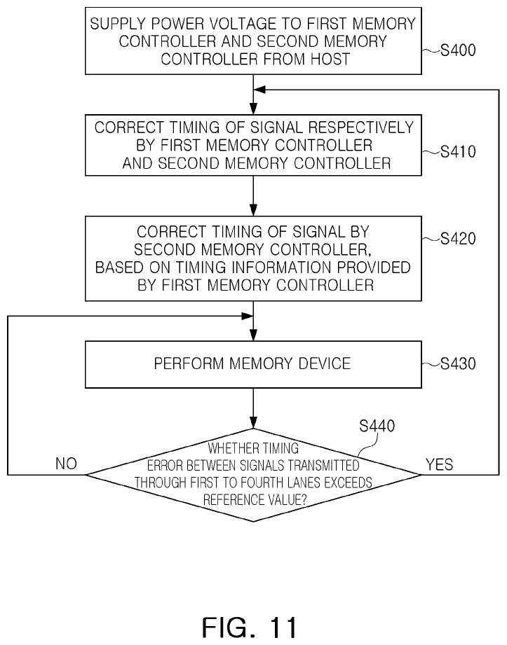

FIG. 11 is a flow chart simply illustrating an operation of a memory device according to some example embodiments.

A host included in a system may supply a power voltage to a first memory controller and a second memory controller, included in a memory device (S400). When the power voltage starts to be supplied to the first memory controller and the second memory controller, the first memory controller and the second memory controller may correct timing of a signal, respectively (S410). When the power voltage starts to be supplied to the memory device, the first memory controller and the second memory controller may correct timing between each of signals transmitted through first to fourth lanes. The first memory controller may correct timing of another lane, based on the timing of the first lane or the timing of the second lane. The second memory controller may correct the timing of another lane, based on the timing of the third lane or the timing of the fourth lane.

The second memory controller may correct timing, based on timing information provided by the first memory controller (S420). In some example embodiments, since the first memory controller and the second memory controller are connected by at least one signal line, the second memory controller may request the timing information from the first memory controller through the at least one signal line, and the first memory controller may provide the timing information to the second memory controller through the at least one signal line.

The first memory controller may provide timing information of the first lane or timing information of the second lane to the second memory controller. The second memory controller may correct timing of the third lane and timing of the fourth lane, based on timing of the first lane or timing of the second lane. The host may supply power to the first memory controller and the second memory controller, and the first memory controller and the second memory controller may correct the timing of all of the signals transmitted through the first to fourth lanes. After correction of the timing is completed in the first memory controller and the second memory controller, the memory device may perform an operation of reading or writing data (S430).

While the memory device is operating, the first memory controller and the second memory controller may check whether a timing error between the signals transmitted through the first to fourth lanes exceeds a reference value (S440). When the timing error between the signals transmitted through the first to fourth lanes exceeds the reference value while the power voltage is supplied, the first memory controller and the second memory controller may correct the timing of each of the signals transmitted through the first to fourth lanes. When the timing error between the signals transmitted through the first to fourth lanes does not exceed the reference value, the memory device may continue to operate.

When power is supplied to the memory device, the timing of the signals transmitted through each of the lanes may be corrected to match. Even while power is supplied to the memory device, the first memory controller and the second memory controller may correct the timing of each of the lanes by determining whether a timing difference between the signals transmitted through the first to fourth lanes exceeds the reference value. When power is supplied to the memory device and while power is supplied, the timing of each of the lanes in the first memory controller and the second memory controller may be corrected to reduce (and/or minimize) an error due to timing skew.

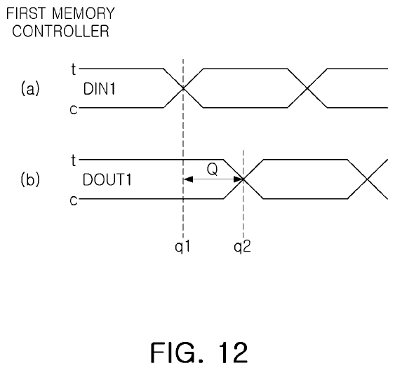

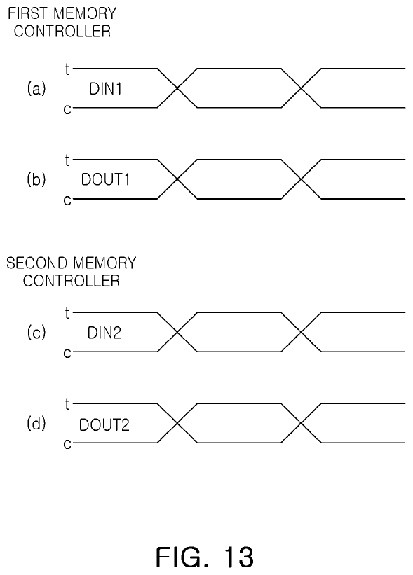

FIGS. 12 and 13 are views simply illustrating an operation of a memory device according to some example embodiments.

When a power voltage starts to be supplied to a memory device, a first memory controller and a second memory controller may correct timing of signals transmitted through first to fourth lanes. In some example embodiments, the timing of each of the signals transmitted through the first to fourth lanes may be changed while the memory device operates, and an error due to timing skew may occur. Therefore, while the power voltage is supplied to the memory device, the first memory controller and the second memory controller may check whether timing skew occurs between the signals transmitted through the first to fourth lanes.

The first memory controller may include a first interface supporting a first lane DIN1 and a second lane DOUT1. When the power voltage starts to be supplied to the first memory controller, the first memory controller may correct timing of the first lane DIN1 and timing of the second lane DOUT1 to match. For example, when the power voltage is supplied, the timing of the first lane DIN1 and the timing of the second lane DOUT1 corrected by the first memory controller may be the same as q1.

As the memory device including the first memory controller operates, timing skew Q, a difference between timing of the first lane DIN1 and timing of the second lane DOUT1, may occur. While power is supplied, the first memory controller may check whether the timing skew Q, which may be a difference between timing q1 of the first lane DIN1 and timing q2 of the second lane DOUT1, exceeds a reference value. When the timing skew Q exceeds the reference value, the first memory controller may correct the timing of the first lane DIN1 and the timing of the second lane DOUT1. When the timing skew Q does not exceed the reference value, the first memory controller may not correct the timing of the first lane DIN1 and the timing of the second lane DOUT1.

In some example embodiments, when the timing skew of at least two lanes exceeds the reference value, the first memory controller and the second memory controller may correct the timing of each of the lanes. The first memory controller and the second memory controller may correct the timing of the first to fourth lanes to reduce (and/or minimize) timing skew, while exchanging timing information through at least one signal line.

In some example embodiments, a system including the memory device may be a system providing UFS4.0, and the signals transmitted through the first to fourth lanes may be transmitted at a high speed of about 24 Gbps. When the timing skew occurs in the signals transmitted through the first to fourth lanes, performance of the memory device may be degraded.

When power is supplied to the memory device and while the power is supplied, the first memory controller and the second memory controller may determine whether the timing skew exceeds the reference value and correct the timing of each of the lanes, to reduce (and/or minimize) an error due to timing skew.

Referring to FIG. 13, timing transmitted to and received from a first memory controller and a second memory controller may be corrected.

The first memory controller may correct timing of a first lane DIN1 and timing of a second lane DOUT1, based on the timing of the first lane DIN1 or the timing of the second lane DOUT1. The second memory controller may correct timing of a third lane DIN2 and timing of a fourth lane DOUT2, based on the timing of the third lane DIN2 or the timing of the fourth lane DOUT2.

The second memory controller may request timing information of the first lane DIN1 or timing information of the second lane DOUT1 from the first memory controller, and the first memory controller may provide the timing information of the first lane DIN1 or the timing information of the second lane DOUT1 to the second memory controller. The second memory controller may correct the timing of the third lane DIN2 and the timing of the fourth lane DOUT2, based on the timing information provided from the first memory controller. A signal transmitted to and received from the first memory controller and the second memory controller may have the same timing through correction of the timing.

In some example embodiments, the memory device may include the first memory controller and the second memory controller, connected by at least one signal line, and the first memory controller and the second memory controller may exchange timing information through the at least one signal line, and may correct timing of the signals transmitted to each of the lanes DIN1, DIN2, DOUT1, and DOUT2, to reduce (and/or minimize) an error due to timing skew.

A memory device according to some example embodiments includes a first memory controller and a second memory controller, connected by at least one signal line, and the first memory controller and the second memory controller may simultaneously transmit and receive a differential signal pair through two lanes, respectively. The first memory controller and the second memory controller may correct timing of signals transmitted through each lane, and may transmit and receive timing information of each lane through the signal line. By transmitting signals through four lanes, a bandwidth that the memory device provides may increase, and by correcting timing of signals transmitted by the first memory controller and the second memory controller through each lane, errors due to timing skew may be minimized.

Various advantages and effects of the inventive concepts are not limited to the above-described contents, and will be more easily understood in the process of explaining specific example embodiments.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments have been illustrated and described above, it will be apparent to those skilled in the art that modifications and variations could be made without departing from the scope of the inventive concepts as defined by the appended claims.

What is claimed is:

1. A memory device comprising:
a first non-volatile memory;
a second non-volatile memory;
a first memory controller including
a first interface, and
the first memory controller configured to control an operation of the first non-volatile memory; and
a second memory controller including
a second interface, and
the second memory controller configured to control an operation of the second non-volatile memory,
wherein the first interface includes
a first lane configured to transmit a first differential input signal pair to the first memory controller, and
a second lane configured to transmit a second differential output signal pair from the first memory controller,
the second interface includes
a third lane configured to transmit a third differential input signal pair to the second memory controller receives, and
a fourth lane configured to transmit a fourth differential output signal pair from second memory controller, and
the first memory controller and the second memory controller are connected by at least one signal line,
the first memory controller and the second memory controller are configured to exchange timing information of a plurality of signals transmitted through the first to fourth lanes through the signal line, and
the first memory controller and the second memory controller are configured to correct a timing of the each of the plurality of signals transmitted through the first to fourth lanes, based on the timing information.

2. The memory device of claim 1, wherein
the first memory controller is configured to generate first corrected timing information based on the first memory controller correcting the timing of the signals transmitted through the first lane and the second lane, and
the second memory controller is configured to generate a second corrected timing information based on the second memory controller correcting the timing of the signals transmitted through the third lane and the fourth lane.

3. The memory device of claim 2, wherein
the second memory controller is configured to receive the first corrected timing information, and
the second memory controller is configured to correct the second corrected timing information to match the first corrected timing information.

4. The memory device of claim 1, wherein
the first memory controller is configured to generate a corrected timing information by correcting the timing of a signal transmitted through the second lane based on the timing of a signal transmitted through the first lane, and
the second memory controller is configured to receive the corrected timing information and correct the timing of signals transmitted through the third lane and the fourth lane, based on the corrected timing information.

5. The memory device of claim 1, wherein
the first memory controller is configured to generate a corrected timing information by correcting the timing of a signal transmitted through the first lane based on the timing of a signal transmitted through the second lane, and
the second memory controller is configured to receive the corrected timing information and corrects the timing of signals transmitted through the third lane and the fourth lane based on the corrected timing information.

6. The memory device of claim 1, wherein
the first memory controller and the second memory controller are configured to correct the timing between each of the signals transmitted through the first to fourth lanes based on a power voltage being supplied.

7. The memory device of claim 1, wherein
the first memory controller and the second memory controller are configured to correct the timing between each of the signals transmitted through the first to fourth lanes based on a difference in the timing between each of the signals transmitted through the first to fourth lanes exceeding a reference value in a power supply voltage.

8. The memory device of claim 1, wherein a general purpose input/output (GPIO) pin of the first memory controller and a GPIO pin of the second memory controller are connected to the at least one signal line.

9. The memory device of claim 1, further comprising:
a package substrate including the first non-volatile memory, the second non-volatile memory, the first memory controller, and the second memory controller mounted on the package substrate,
wherein the first memory controller and the second memory controller are on the package substrate between the first non-volatile memory and the second non-volatile memory in a first direction, the first direction parallel to an upper surface of the package substrate.

10. The memory device of claim 9, wherein
the first memory controller is on the package substrate, and
the second memory controller is below the first memory controller in a second direction, the second direction perpendicular to the first direction and parallel to the upper surface of the package substrate.

11. The memory device of claim 9, wherein
the first memory controller and the second memory controller are connected to the package substrate through a plurality of pads, and
the first non-volatile memory and the second non-volatile memory are connected to the package substrate through a plurality of wires.

12. The memory device of claim 9, wherein
a first signal line connects the first memory controller and the first non-volatile memory,
a second signal line connects the second memory controller and the second non-volatile memory, and
the first signal line and the second signal line are in a same layer on the package substrate.

13. The memory device of claim 12, wherein the at least one signal line, the first signal line, and the second signal line do not overlap.

14. The memory device of claim 1, further comprising:
a package substrate including the first non-volatile memory, the second non-volatile memory, the first memory controller, and the second memory controller mounted on the package substrate,
wherein the first memory controller and the first non-volatile memory are on the package substrate in a first direction, the first direction parallel to an upper surface of the package substrate, and
the second memory controller is below the first memory controller in a second direction, the second direction perpendicular to the first direction and parallel to the upper surface of the package substrate, and
the second non-volatile memory is below the first non-volatile memory.

15. The memory device of claim 1, wherein the first memory controller and the second memory controller is a same memory controller.

16. The memory device of claim 1, wherein the second memory controller is configured to rotate the first memory controller 180 degrees.

17. The memory device of claim 1, wherein the memory device is a universal flash storage (UFS).

18. The memory device of claim 1, wherein
the first differential input signal pair and the third differential input signal pair are independent of each other, and
the second differential output signal pair and the fourth differential output signal pair are independent of each other.

19. A memory device comprising:
a first non-volatile memory;
a second non-volatile memory;
a first memory controller configured to control an operation of the first non-volatile memory; and
a second memory controller configured to control an operation of the second non-volatile memory,
wherein the first memory controller and the second memory controller are connected by at least one signal line, and
the at least one of the first memory controller or the second memory controller is configured to limit performance of the at least one of the first memory controller or the second memory controller based on a temperature of at least one of the first memory controller or the second memory controller exceeding a reference temperature, and
the at least one of the first memory controller or the second memory controller is configured to limit performance of other memory controller through the at least one signal line.

20. A memory device comprising:
a first non-volatile memory;
a second non-volatile memory;
a first memory controller configured to control an operation of the first non-volatile memory; and
a second memory controller configured to control an operation of the second non-volatile memory,
wherein the first memory controller and the second memory controller are connected by at least one signal line,
the second memory controller is configured to request a corrected timing information of a signal transmitted to and received from the first memory controller, and
the first memory controller is configured to provide the corrected timing information to the second memory controller through the at least one signal line.
